(19) United States
(12) Patent Application Publication
(10) Pub. No.: US 2019/0221719 A1
(43) Pub. Date: Jul. 18, 2019

(54) BACKLIGHT SOURCE

(71) Applicant: HUIZHOU CHINA STAR OPTOELECTRONICS TECHNOLOGY CO., LTD., Huizhou Guangdong (CN)

(72) Inventor: Yongyuan QIU, Huizhou Guangdong (CN)

(21) Appl. No.: 16/008,722

(22) Filed: Jun. 14, 2018

Related U.S. Application Data
(63) Continuation of application No. PCT/CN2018/078802, filed on Mar. 13, 2018.

(30) Foreign Application Priority Data
Jan. 17, 2018 (CN) 201810044654.2

(51) Int. Cl. H01L 33/50; H01L 33/56; H01L 33/60; H01L 33/48

(52) U.S. Cl. CPC H01L 33/502; H01L 33/483; H01L 33/60; H01L 33/56

(57) ABSTRACT

The present disclosure relates to a backlight source, including: a top substrate, a bottom substrate including a flexible circuit board, a reflective layer configured on a side of the top substrate, a light conversion layer, made of quantum dot (QD) material, configured on a side of the reflective layer, at least one light-emitting diode (LED) blue-light emitting chip configured on a side of the bottom substrate, a silicone layer configured between the light conversion layer and the bottom substrate. The opening is configured to change a refractive direction of a central optical path and to reduce an intensity of central light beams, such that light beams emitted from the at least one LED blue-light emitting chip are reflected by the reflective layer after passing through the corresponding opening to uniformly excite the QD material of the light conversion layer, and to eliminate yellow halo phenomenon.

### CROSS REFERENCE TO RELATED APPLICATIONS

This application is a continuing application of PCT Patent Application No. PCT/CN2018/078802, entitled “BACKLIGHT SOURCE”, filed on Mar. 13, 2018, which claims priority to Chinese Patent Application No. 201810044654.2, filed on Jan. 17, 2018, both of which are hereby incorporated in its entireties by reference.

### BACKGROUND

### 1. Technical Field

The present disclosure relates to display field, and more particularly to a backlight source.

### 2. Description of Related Art

Quantum dot (QD) is also referred to as nanocrystalline, and is made of nanoparticles composed of II-VI or III-V elements. The diameter of the nanoparticles is in a range from 1 to 10 nanometers (nm).

The photoelectric characteristics of the QD relate to the size and the shape. The energy band gap of the QD is inversely proportional to the size. That is, the smaller the size of the QD is, the wider the band gap will be. The wide band gap of the QD may cause the emitting light shifting to the blue-light. Thus, the QD with different emitting spectrums may be obtained by controlling the size of the QD. According to the well-known emitting spectrums of the QD, the half-width of the QD luminescence spectrum (about 50 to 60 nm) is narrower than the half-width of the green phosphor (about 80 nm) commonly used in current light-emitting diodes (LEDs) and the half-width of the red phosphor (about 100 nm). Therefore, when adopted in the display devices, the QD may cooperate with the photoresist to achieve high penetration rate and guarantee high color gamut with the national television system committee (NTSC) standard.

Generally, in commercial, the core of the QD is made of cadmium selenide (CdSe), and the shell of the QD is made of cadmium sulfide (CdS). The QD material may fail due to high temperature, water vapor, and oxygen. Therefore, the QD material needs to be protected in commercial use. The current protection methods may include the following two. (I) Forming the QD film. The water/oxygen barrier layer, which is made of polyethylene terephthalate (PET), is formed to package the QD material. (II) Forming the quantum bar structure. The hollow glass tube is adopted to package the QD material.

However, in the first protection method, the QD film requires a great amount QD material, and it is difficult to control the color in the backlight source, which may result in low mass production. In the second protection method, the quantum bar structure may not be adopted in direct type backlight structure. When adopting the quantum bar structure in the side-type backlight structure, the problem of alignment between the quantum bar and the LED light bar will become worse, which may result in a region where a large amount of energy is attenuated. Moreover, the narrow bezel design may not be achieved when adopting the quantum bar structure in the side-type backlight source structure

In order to overcome the problems in the current protection methods of the QD material, adopting the QD as phosphors directly encapsulated in LEDs is developed. However, the direct influence of the heat from LED light-emitting chips to the QD material still needs to be solved. The far-field packaging method is usually adopted in the current protection methods to solve the direct influence of the heat of the LED light-emitting chips to the QD material. The problem of the far-field packaging is that the optical path may be different according to the excitation level of the phosphor. In particular, the optical path formed by large-angle light beams will be even longer when the QD phosphor is excited. Thus, the more phosphors are excited, the easier the yellow halo phenomenon will occur. That is, the edge area of the LED is more yellow when comparing with the center of the LED. In addition, the isolation of water and oxygen has not been well resolved in the current protection methods of the QD material.

### SUMMARY

In one aspect, the present disclosure relates to a backlight source, including: a top substrate; a bottom substrate including a flexible circuit board; a reflective layer configured on a side of the top substrate, wherein the side of the top substrate faces toward the bottom substrate; a light conversion layer configured on a side of the reflective layer, wherein the side of the reflective layer faces toward the bottom substrate, and the light conversion layer is made of quantum dot (QD) material; at least one light-emitting diode (LED) blue-light emitting chip configured on a side of the bottom substrate, wherein the side of the bottom substrate faces toward the top substrate, and each of the LED blue-light emitting chips electrically connects to the flexible circuit board on the bottom substrate; a silicone layer configured between the light conversion layer and the bottom substrate, wherein the silicone layer covers each of the LED blue-light emitting chips; wherein a side of the silicone layer, facing toward the light conversion layer, is configured with at least one opening corresponding to the at least one LED blue-light emitting chip, the opening is configured to change a refractive direction of a central optical path and to reduce an intensity of central light beams, such that light beams emitted from the at least one LED blue-light emitting chip are reflected by the reflective layer after passing through the corresponding opening to uniformly excite the QD material of the light conversion layer, and to eliminate yellow halo phenomenon.

A diameter of each of the openings is configured to be gradually decreased from one side of the light conversion layer along a direction facing away from the light conversion layer.

The backlight source further includes a water/oxygen barrier layer configured to prevent water and oxygen in air from invading the light conversion layer; wherein the water/oxygen barrier layer is configured between the light conversion layer and the silicone layer, and the water/oxygen barrier layer covers the light conversion layer.

The backlight source further comprises two retaining walls configured to prevent the light beams from being leaked via edges of the backlight source; wherein the two retaining walls are respectively configured on two opposite sides of the silicone layer and are fixed with the silicone layer, and the two retaining walls are further fixed with the top substrate and the bottom substrate.

The two retaining walls are trapezoidal cylinders, wherein: end surfaces of the two retaining walls fixed with the silicone layer are respectively configured to be an inclined plane, and an angle formed by the inclined plane of the retaining walls and the bottom plate is less than 90 degrees.

The two retaining walls are made of polycyclohexyl dimethylene terephthalate resin (PCT) or epoxy molding compound (EMC).

The bottom substrate is a transparent flexible substrate made of polyimide (PI) or polyethylene terephthalate (PET), or the bottom substrate is a sapphire substrate.

The top substrate is made of glass or aluminum.

The top substrate is made of glass, and the reflective layer is a single layer structure or a stacked layer structure; the reflective layer of the single layer structure is made of PET or polypropylene (PP); the reflective layer of the stacked layer structure comprises a bottom layer made of PET or PP, and at least one top layer made of silver.

The top substrate is made of aluminum, and the reflective layer is a single layer structure made of silver; and the top substrate and the two retaining walls are integrally formed.

In another aspect, the present disclosure relates to an another backlight source, including: a top substrate; a bottom substrate including a flexible circuit board; a reflective layer configured on a side of the top substrate, wherein the side of the top substrate faces toward the bottom substrate; a light conversion layer configured on a side of the reflective layer, wherein the side of the reflective layer faces toward the bottom substrate, and the light conversion layer is made of quantum dot (QD) material; at least one light-emitting diode (LED) blue-light emitting chip configured on a side of the bottom substrate, wherein the side of the bottom substrate faces toward the top substrate, and each of the LED blue-light emitting chips electrically connects to the flexible circuit board on the bottom substrate; a silicone layer configured between the light conversion layer and the bottom substrate, wherein the silicone layer covers each of the LED blue-light emitting chips; wherein a side of the silicone layer, facing toward the light conversion layer, is configured with at least one opening corresponding to the at least one LED blue-light emitting chip, the opening is configured to change a refractive direction of a central optical path and to reduce an intensity of central light beams, such that light beams emitted from the at least one LED blue-light emitting chip are reflected by the reflective layer after passing through the corresponding opening to uniformly excite the QD material of the light conversion layer, and to eliminate yellow halo phenomenon.

A diameter of each of the openings is configured to be gradually decreased from one side of the light conversion layer along a direction facing away from the light conversion layer.

The backlight source further includes a water/oxygen barrier layer configured to prevent water and oxygen in air from invading the light conversion layer; wherein the water/oxygen barrier layer is configured between the light conversion layer and the silicone layer, and the water/oxygen barrier layer covers the light conversion layer.

The backlight source further comprises two retaining walls configured to prevent the light beams from being leaked via edges of the backlight source; wherein the two retaining walls are respectively configured on two opposite sides of the silicone layer and are fixed with the silicone layer, and the two retaining walls are further fixed with the top substrate and the bottom substrate.

The two retaining walls are trapezoidal cylinders, wherein: end surfaces of the two retaining walls fixed with the silicone layer are respectively configured to be an inclined plane, and an angle formed by the inclined plane of the retaining walls and the bottom plate is less than 90 degrees.

The two retaining walls are made of polycyclohexyl dimethylene terephthalate resin (PCI) or epoxy molding compound (EMC).

The bottom substrate is a transparent flexible substrate made of polyimide (PI) or polyethylene terephthalate (PET), or the bottom substrate is a sapphire substrate.

The top substrate is made of glass or aluminum.

The top substrate is made of glass, and the reflective layer is a single layer structure or a stacked layer structure; the reflective layer of the single layer structure is made of PET or polypropylene (PP); the reflective layer of the stacked layer structure comprises a bottom layer made of PET or PP, and at least one top layer made of silver.

The top substrate is made of aluminum, and the reflective layer is a single layer structure made of silver; and the top substrate and the two retaining walls are integrally formed.

In view of the above, the side of the silicone layer, facing toward the light conversion layer, is configured with the opening corresponding to each of the LED blue-light emitting chips. The opening is configured to change the refractive direction of the central optical path and reduce intensity of central light beams. Such that, the light beams emitted from each of the LED blue-light emitting chips are reflected by the reflective layer after passing through the corresponding opening to uniformly excite the QD material of the light conversion layer, so as to eliminate yellow halo phenomenon. The water/oxygen barrier layer is further configured on the light conversion layer. The water/oxygen barrier layer is configured to prevent the water and oxygen in the air from invading the light conversion layer.

### BRIEF DESCRIPTION OF THE DRAWINGS

FIG. 1 is a schematic view of a portion of a backlight source in accordance with one embodiment in the present disclosure.

FIG. 2 is a schematic view of a portion of the backlight source in accordance with another embodiment in the present disclosure.

### DETAILED DESCRIPTION

Following embodiments of the invention will now be described in detail hereinafter with reference to the accompanying drawings.

In the drawings, the thicknesses of layers and regions may be exaggerated for clarity. Same reference numerals refer to the same components throughout the specification and the drawings.

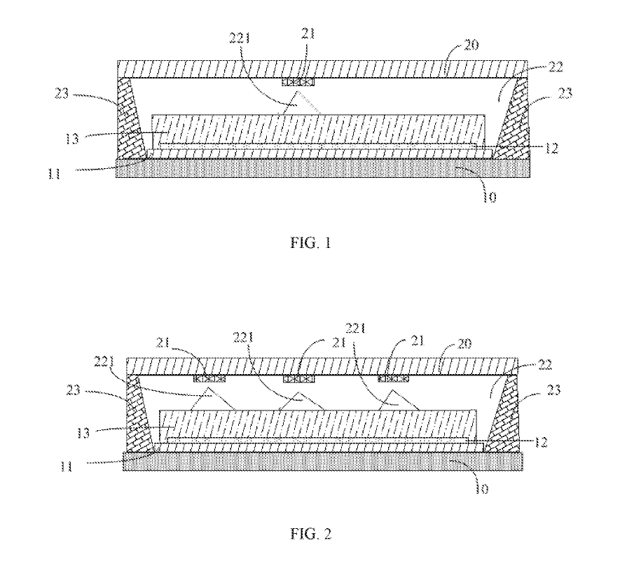

Referring to FIG. 1 and FIG. 2, the present disclosure relates to a backlight, including: a top substrate 10, a bottom substrate 20 including a flexible circuit board, a reflective layer 11, a light conversion layer 12, at least one light-emitting diode (LED) blue-light emitting chip 21, and a silicone layer 22.

Specifically, the reflective layer 11 is configured on a side of the top substrate 10, wherein the side of the top substrate 10 faces toward the bottom substrate 20.

The light conversion layer 12 is configured on a side of the reflective layer 11, wherein the side of the reflective layer 11 faces toward the bottom substrate 20, and the light conversion layer 12 is made of quantum dot (QD) material.

The at least one LED blue-light emitting chip 21 is configured on a side of the bottom substrate 20, wherein the side of the bottom substrate 20 faces toward the top substrate 10, and each of the LED blue-light emitting chips 21 electrically connects to the flexible circuit hoard on the bottom substrate 20.

The silicone layer 22 is configured between the light conversion layer 12 and the bottom substrate 20, wherein the silicone layer 22 covers each of the LED blue-light emitting chips 21.

A side of the silicone layer 22, facing toward the light conversion layer 12, is configured with at least one opening 221 corresponding to the at least one LED blue-light emitting chip 21. The opening 221 is configured to change a refractive direction of a central optical path and to reduce an intensity of central light beams. Such that light beams emitted from the at least one LED blue-light emitting chip 21 are reflected by the reflective layer after passing through the corresponding opening 221 to uniformly excite the QD material of the light conversion layer 12, and to eliminate yellow halo phenomenon.

It is noted that the flexible circuit board on the bottom substrate 20 is able to drive each of the LED blue-light emitting chip 21 to illuminate. Each of the LED blue light emitting chip 21 emits the light beams in Lambertian-type. That is, energy in a central position is higher. The emitted light beams enter the corresponding openings 221 to form an optical path deflection and to reduce the amount of the light beams concentrated at the central position, so as to reduce the intensity of central light beams. Such that the QD material of the light conversion layer 12 may uniformly be excited and the yellow halo phenomenon may be eliminated.

In one example, a diameter of each of the openings 221 is configured to be gradually decreased from one side of the light conversion layer 12 along a direction facing away from the light conversion layer 12. That is, the opening 221 is of a trumpet-shape (i.e., an inverted-trapezoidal structure) or a triangular-shape (i.e., an inverted-tapered structure). Such that the amount and the intensity of the central light beams emitted from the corresponding opening 221 of each of the LED blue-light emitting chip 21 may be reduced.

In one example, the backlight source further includes a water/oxygen barrier layer 13 configured to prevent water and oxygen in air from invading the light conversion layer 12. The water/oxygen barrier layer 13 is configured between the light conversion layer 12 and the silicone layer 22, and the water/oxygen barrier layer 13 covers the light conversion layer 12 to prevent the water and oxygen from invading the light conversion layer 12.

In one example, the backlight source further includes two retaining walls 23 configured to prevent the light beams from being leaked via edges of the backlight source. The two retaining walls 23 arc respectively configured on two opposite sides of the silicone layer 22 and are fixed with the silicone layer 22. The two retaining walls 23 are further fixed with the top substrate 10 and the bottom substrate 20. Such that the light beams emitted from the LED blue-light emitting chip 21 may be concentrated, and the intensity-reduced resulting from the light beams being leaked via the edges of the backlight source may be avoided. The two retaining walls 23 are made of polycyclohexyl dimethylene terephthalate resin (PCT) or epoxy molding compound (EMC).

In one example, the two retaining walls 23 are trapezoidal cylinders. End surfaces of the two retaining walls 23 fixed with the silicone layer 22 are respectively configured to be an inclined plane, and an angle formed by the inclined plane of the retaining walls and the bottom plate 20 is less than 90 degrees. The intensity of the central light beams emitted from the LED blue-light emitting chip 21 may be increased by a configuration of the inclined plane.

In one example, the bottom substrate 20 is a transparent flexible substrate made of polyimide (PI) or polyethylene terephthalate (PET). In another example, the bottom substrate 20 is a sapphire substrate. The top substrate 10 is made of glass or aluminum.

In one example, the top substrate 10 is made of glass, and the reflective layer 11 is a single layer structure or a stacked layer structure. The reflective layer 11 of the single layer structure is made of PET or polypropylene (PP) to form a white reflective sheet of the single layer structure. The reflective layer 11 of the stacked layer structure includes a bottom layer made of PET or PP, and at least one top layer made of silver, to form the reflective layer of the stacked layer structure. It is noted that when the top layer of silver includes multiple layers, a multilayer Bragg reflection may be formed.

In another example, the top substrate 10 is made of aluminum, and the reflective layer 11 is a single layer structure made of silver. That is, silver is coated on a surface of the top substrate 10 to form the reflective layer 11.

In one example, the top substrate 10 and the two retaining walls 23 are integrally formed when the top substrate 10 is made of aluminum. In another example, the two retaining walls 23 may he integrally formed with the bottom substrate 20, and the two retaining walls 23 and the top substrate 10 may be fixed by ultraviolet (UV) glue.

It is noted that when the backlight source includes one LED blue-light emitting chip 21, as shown in FIG. 1, the backlight source may be a single structure and may be adopted to liquid crystal displays with a direct type backlight structure. Or, when the backlight source includes a plurality of LED blue-light emitting chips 21, as shown in FIG. 2, the backlight source may be a light bar structure and may be adopted to liquid crystal displays with a side-type backlight structure.

In view of the above, the side of the silicone layer, facing toward the light conversion layer, is configured with the opening corresponding to each of the LED blue-light emitting chips. The opening is configured to change the refractive direction of the central optical path and reduce intensity of central light beams. Such that, the light beams emitted from each of the LED blue-light emitting chips are reflected by the reflective layer after passing through the corresponding opening to uniformly excite the QD material of the light conversion layer, so as to eliminate yellow halo phenomenon. The water/oxygen barrier layer is further configured on the light conversion layer. The water/oxygen barrier layer is configured to prevent the water and oxygen in the air from invading the light conversion layer.

The above description is merely the embodiments in the present disclosure, the claim is not limited to the description thereby. The equivalent structure or changing of the process of the content of the description and the figures, or to implement to other technical field directly or indirectly should be included in the claim.

1. A backlight source, comprising:
a top substrate;
a bottom substrate comprising a flexible circuit board;
a reflective layer configured on a side of the top substrate, wherein the side of the top substrate faces toward the bottom substrate;
a light conversion layer configured on a side of the reflective layer, wherein the side of the reflective layer faces toward the bottom substrate, and the light conversion layer is made of quantum dot (QD) material;
at least one light-emitting diode (LED) blue-light emitting chip configured on a side of the bottom substrate, wherein the side of the bottom substrate faces toward the top substrate, and each of the LED blue-light emitting chips electrically connects to the flexible circuit board on the bottom substrate;
a silicone layer configured between the light conversion layer and the bottom substrate, wherein the silicone layer covers each of the LED blue-light emitting chips;
wherein a side of the silicone layer, facing toward the light conversion layer, is configured with at least one opening corresponding to the at least one LED blue-light emitting chip, the opening is configured to change a refractive direction of a central optical path and to reduce an intensity of central light beams, such that light beams emitted from the at least one LED blue-light emitting chip are reflected by the reflective layer after passing through the corresponding opening to uniformly excite the QD material of the light conversion layer, and to eliminate yellow halo phenomenon.

2. The backlight source according to claim 1, wherein a diameter of each of the openings is configured to be gradually decreased from one side of the light conversion layer along a direction facing away from the light conversion layer.

3. The backlight source according to claim 2, wherein the backlight source further comprises a water/oxygen barrier layer configured to prevent water and oxygen in air from invading the light conversion layer;
wherein the water/oxygen barrier layer is configured between the light conversion layer and the silicone layer, and the water/oxygen barrier layer covers the light conversion layer.

4. The backlight source according to claim 3, wherein the backlight source further comprises two retaining walls configured to prevent the light beams from being leaked via edges of the backlight source;
wherein the two retaining walls are respectively configured on two opposite sides of the silicone layer and are fixed with the silicone layer, and the two retaining walls are further fixed with the top substrate and the bottom substrate.

5. The backlight source according to claim 4, wherein the two retaining walls are trapezoidal cylinders, wherein:
end surfaces of the two retaining walls fixed with the silicone layer are respectively configured to be an inclined plane, and an angle formed by the inclined plane of the retaining walls and the bottom plate is less than 90 degrees.

6. The backlight source according to claim 5, wherein the two retaining walls are made of polycyclohexyl dimethylene terephthalate resin (PCT) or epoxy molding compound (EMC).

7. The backlight source according to claim 1, wherein the bottom substrate is a transparent flexible substrate made of polyimide (PI) or polyethylene terephthalate (PET).

8. The backlight source according to claim 7, wherein the top substrate is made of glass or aluminum.

9. The backlight source according to claim 8, wherein the top substrate is made of glass, and the reflective layer is a single layer structure or a stacked layer structure;
the reflective layer of the single layer structure is made of PET or polypropylene (PP);
the reflective layer of the stacked layer structure comprises a bottom layer made of PET or PP, and at least one top layer made of silver.

10. The backlight source according to claim 8, wherein the top substrate is made of aluminum, and the reflective layer is a single layer structure made of silver; and
the top substrate and the two retaining walls are integrally formed.

11. A backlight source, comprising:
a top substrate;
a bottom substrate comprising a flexible circuit board;
a reflective layer configured on a side of the top substrate, wherein the side of the top substrate faces toward the bottom substrate;
a light conversion layer configured on a side of the reflective layer, wherein the side of the reflective layer faces toward the bottom substrate, and the light conversion layer is made of QD material;
at least one LED blue-light emitting chip configured on a side of the bottom substrate, wherein the side of the bottom substrate faces toward the top substrate, and each of the LED blue-light emitting chips electrically connects to the flexible circuit board on the bottom substrate;
a silicone layer configured between the light conversion layer and the bottom substrate, wherein the silicone layer covers each of the LED blue-light emitting chips;
wherein a side of the silicone layer, facing toward the light conversion layer, is configured with at least one opening corresponding to the at least one LED blue-light emitting chip, the opening is configured to change a refractive direction of a central optical path and to reduce an intensity of central light beams, such that light beams emitted from the at least one LED blue-light emitting chip are reflected by the reflective layer after passing through the corresponding opening to uniformly excite the QD material of the light conversion layer, and to eliminate yellow halo phenomenon; and
the backlight source further comprises a water/oxygen barrier layer configured to prevent water and oxygen in air from invading the light conversion layer;
wherein the water/oxygen barrier layer is configured between the light conversion layer and the silicone layer, and the water/oxygen barrier layer covers the light conversion layer.

12. The backlight source according to claim 11, wherein a diameter of each of the openings is configured to be gradually decreased from one side of the light conversion layer along a direction facing away from the light conversion layer.

13. The backlight source according to claim 4, wherein the backlight source further comprises two retaining walls configured to prevent the light beams from being leaked via edges of the backlight source;
wherein the two retaining walls are respectively configured on two opposite sides of the silicone layer and are fixed with the silicone layer, and the two retaining walls are further fixed with the top substrate and the bottom substrate.

14. The backlight source according to claim 13, wherein the two retaining walls are trapezoidal cylinders, wherein:
end surfaces of the two retaining walls fixed with the silicone layer are respectively configured to be an inclined plane, and an angle formed by the inclined plane of the retaining walls and the bottom plate is less than 90 degrees.

15. The backlight source according to claim 14, wherein the two retaining walls are made of PCT or EMC.

16. The backlight source according to claim 15, wherein the bottom substrate is a transparent flexible substrate made of PI or PET, or the bottom substrate is a sapphire substrate.

17. The backlight source according to claim 16, wherein the top substrate is made of glass or aluminum.

18. The backlight source according to claim 17, wherein the top substrate is made of glass, and the reflective layer is a single layer structure or a stacked layer structure;
the reflective layer of the single layer structure is made of PET or PP;
the reflective layer of the stacked layer structure comprises a bottom layer made of PET or PP, and at least one top layer made of silver.

19. The backlight source according to claim 18, wherein the top substrate is made of aluminum, and the reflective layer is a single layer structure made of silver; and
the top substrate and the two retaining walls are integrally formed.
